(19) United States
(12) Patent Application Publication
(10) Pub. No.: US 2005/0275043 A1
(43) Pub. Date: Dec. 15, 2005

(54) Novel semiconductor device design

(76) Inventors: Chien-Chao Huang, Hsin-Chu (TW); Hao-Yu Chen, Kaohsiung (TW); Fu-Liang Yang, Hsin-Chu (TW); Cheng-Chuan Huang, Hsin-Chu (TW); Tong-Heuan Chung, Hsin-Chu (TW)

Correspondence Address: SLATER & MATSIL, L.L.P., 17950 PRESTON ROAD, SUITE 1000, DALLAS, TX, 75252, US

(21) Appl. No.: 11/146,692

(22) Filed: Jun. 7, 2005

Related U.S. Application Data
(60) Provisional application No. 60/578,726, filed on Jun. 10, 2004.
(60) Provisional application No. 60/582,931, filed on Jun. 25, 2004.

(51) Int. Cl. H01L 29/76

(52) U.S. Cl. 257/401

(57) ABSTRACT

An integrated circuit having small layout area and a method of forming the same are provided. A slant contact is formed by shifting a portion of a contact a distance less than a whole dimension of the contact along the direction shifted. By using slant contacts, the optical proximity effect is reduced, the device density in the integrated circuit is increased and cross talk is reduced. In the preferred embodiment, the slant contact is combined with other techniques such as compound interconnection, butted local interconnection and slim spacers to reduce the layout area. In another embodiments, a six-transistor SRAM cell can be designed with a slant contact, compound interconnection and butted local interconnection to reduce the layout area.

This application claims the benefit of U.S. Provisional Application No. 60/578,726, filed on Jun. 10, 2004, entitled “SRAM Cell Design,” and further claims the benefit of U.S. Provisional Application No. 60/582,931, filed on Jun. 25, 2004, entitled “SRAM Cell Design,” which applications are hereby incorporated herein by reference.

### TECHNICAL FIELD

This invention relates generally to semiconductor devices, and specifically to the design of semiconductor devices having small layout areas.

### BACKGROUND

With the scaling of VLSI circuits, more devices are put into a single chip. This not only requires the shrinking of device size, but it also requires the improvement of layout techniques.

One example is static random access memory (SRAM). Due to the high capacity requirement of the memory, being able to reduce the layout area is especially important. The elements of the devices are laid out closely to save space. However, problems arise when elements are so close that optical proximity effects occur. Optical proximity effects are due to light diffraction and interference between closely spaced features on the reticle, and the widths of lines in the lithographic image are affected by other nearby features. One component of the proximity effect is optical interaction among neighboring features; other components arise from similar mechanisms in the resist and etch processes.

Optical proximity correction (OPC) is one of the methods adopted to compensate for the light diffraction effect as a post layout process. It reduces or eliminates the optical proximity effect. However, the process is time-consuming and the results are still limited by the original layout quality. It is more advantageous to avoid the optical proximity correction than to correct the effects. Therefore, contact design and layout techniques are studied to make the layout area smaller without incurring optical proximity effects.

### SUMMARY OF THE INVENTION

The preferred embodiments of the present invention present a method of designing integrated circuits.

In accordance with one aspect of the present invention, a slant contact is formed by shifting a portion of a contact a distance less than a whole dimension of the contact along the direction shifted. The slant contact typically has an oval shape due to optical and etching effects. With slant contacts, the optical proximity effect is reduced or eliminated. Using slant contacts increases the device density in an integrated circuit and reduces cross talk.

In accordance with another aspect of the present invention, a six-transistor SRAM cell is designed using a compound interconnection having a doped semiconductor covered with a silicide. The compound interconnection interconnects a source of a pass gate transistor, a drain of a pull down transistor and a drain of a pull up transistor. The compound interconnection includes a doped semiconductor, which has a p+ and an n+ region in physical contact with each other and a silicide on the doped semiconductor to reduce resistance.

In accordance with another aspect of the present invention, a butted local interconnection preferably connects a gate of one transistor to a source/drain of another transistor. The contact resistance and layout area are significantly reduced by using a butted local interconnection.

In accordance with yet another aspect of the present invention, a slant contact, butted local interconnection, compound interconnection and slim spacers are combined to minimize the layout area and reduce optical proximity effects.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic circuit diagram of a typical six-transistor SRAM;

FIG. 2 illustrates a conventional layout of a six-transistor SRAM layout;

FIG. 3 illustrates a preferred embodiment having slant contacts;

FIG. 4 illustrates a detailed view of a slant contact;

FIG. 5 illustrates a slant contact having a narrow middle portion;

FIGS. 6a and 6b illustrate variations of slant contacts;

FIG. 7 illustrates a slant contact having an oval shape due to optical and etching effects;

FIG. 8 illustrates a cross-sectional view of a butted local interconnection along line A-A′ in FIG. 3;

FIG. 9 illustrates another embodiment of the butted local interconnection wherein the thickness a contact is less than the height of the gate it covers; and

FIG. 10 illustrates a cross-sectional view of a compound interconnection along line B-B′ in FIG. 3.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Typically, layouts are made along grids or reticles having two directions vertical to each other, namely, x and y directions. In order to reduce the optical proximity between neighboring contacts, the contacts have to be sufficiently separated. It is preferred that the contacts are evenly distributed to make better use of the layout area. However, it is hard to place a long contact without incurring excessive loss of layout space. This is especially true for the layout of SRAM cells due to the high density of the memory chip. The preferred embodiments of the present invention propose a novel method using slant contacts. The preferred embodiments also provide several other techniques that are combined to form a compact circuit.

For illustration purposes, a typical six-transistor (6T) SRAM cell is used to demonstrate layout design. FIG. 1 illustrates a schematic circuit diagram of a 6T SRAM cell. One skilled in the art will recognize that the concept introduced in the preferred embodiments applies to other integrated circuit designs as well. The 6T SRAM cell comprises a pass gate transistor 10 and a latch, which includes transistors 12, 14, 16 and 18. The gate 1 of the pass gate transistor 10 is controlled by a word line WL that determines whether the current SRAM cell is selected or not. The latch formed of the pull up transistor 12, pull down transistor 14, transistor 16 and transistor 18 stores a state. The stored state can be read through the bit line BL.

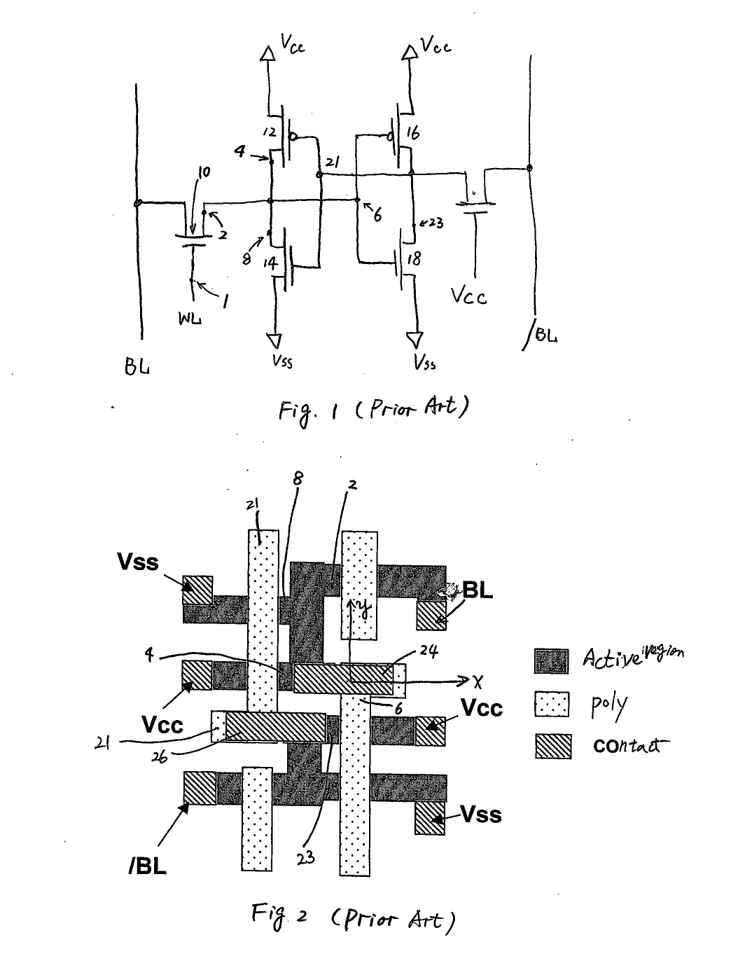

FIG. 2 illustrates a conventional layout of the 6T SRAM shown in FIG. 1, wherein transistors can be identified by identifying corresponding reference numbers of their gates, sources and drains. The contact 24 connects two features. The first feature is the active region 4 of the transistor 12, and the second feature is the gate poly 6 of the transistor 18. The contact 26 also connects two features. The first feature is the active region 23 of the transistor 18, and the second feature is the gate poly 21 of the transistors 12 and 14. Throughout the description, the term “feature” is used to refer to components in the integrated circuit that are connected by slant contacts, butted local interconnections, and compound interconnections, etc., as will be discussed in subsequent paragraphs. Each feature will be aligned to either an x or y direction. The contacts 24 and 26 are rectangles with lengths in x direction and widths in y direction. It is noted that the left portion of the contact 24 is close to the right portion of the contact 26. To avoid the proximity effect between contacts 24 and 26, it is desirable that the contact 24 is moved up and/or the contact 26 is moved down. However, the moving of the contacts 24 may cause the proximity effect between contacts 24 and BL, and the moving of the contact 26 may cause the proximity effect between contacts 26 and /BL.

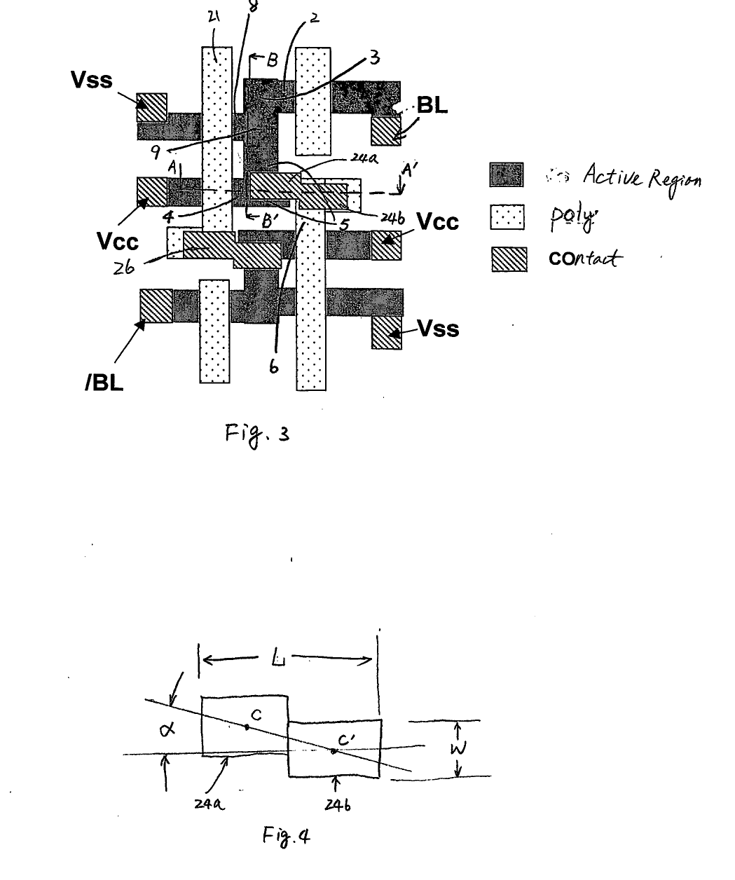

FIG. 3 illustrates a preferred embodiment, wherein the circuit in FIG. 1 is laid out using slant contacts. For performance and reliability reasons, in the preferred embodiment, the transistors preferably include gate dielectrics formed of oxide-based material having a dielectric constant (K) value of greater than about 5, and spacers having widths of less than about 350 Å. The contacts 24 and 26 are slant contacts. They are so named because their current directions are not aligned with the normal x or y direction. The details of the slant contact are shown in FIG. 4. The typical rectangle shaped contact includes two portions, the left portion 24a and the right portion 24b. Both left and right portions 24a and 24b are rectangles or squares. The left portion 24a is shifted up a distance less than its width W. If a line is drawn between the center point C of the left portion 24a and the center point C′ of the right portion 24b, the new length direction (or the new current direction) is along the line C-C′, and the new width direction is the direction perpendicular to the line C-C′. The slant contact has a tilt angle α with the original direction it tilts from. It is found from FIG. 3 that a shift may cause a significant effect on the layout. For example, assuming the original distance between contacts 24 and 26 equals their width, by shifting the left portion 24a of the contact 24 up one quarter of the contact width W, and shifting the right portion 26b of the contact 26 down one quarter of the contact width W, the contact distance may increased as much as 50%. The increase of the distance causes significant reduction of the optical proximity effect between contacts 24 and 26 even though the distance between contacts 24 and BL and the distance between contacts 26 and /BL stay the same.

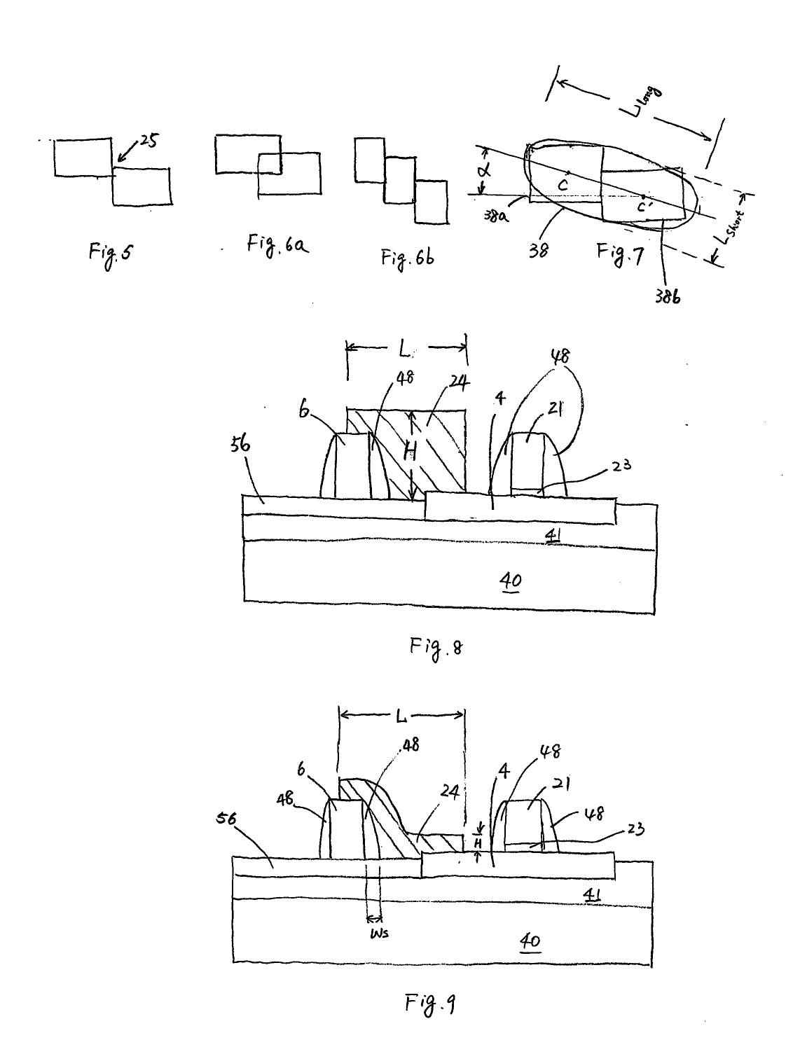

In the preferred embodiment, the slant contact is formed by shifting a portion of the contact along either horizontal layout direction, sometimes referred to as x direction, or orthogonal layout direction, sometimes referred to as y direction. When the tilt angle α increases, the slant contact may have a very narrow region 25 in the middle, as shown in FIG. 5. Therefore, in some embodiments, the slant contact is preferably formed by shifting a portion along both x and y direction so that the contact appears to be stacked partially, as shown in FIG. 6a. When a contact is long and the slant angle α is great, it is desired that the slant contact is formed of more than two shifted rectangles, as shown in FIG. 6b. This ensures that the width of the slant contact is substantially uniform throughout the length. Contacts with uniform width are less prone to failure due to high current density.

Due to optical effect and etching effects, the slant contact is typically oval-shaped, such as the oval 38 shown in FIG. 7. The oval 38, which is formed by designing two interconnected contacts 38a and 38b, has a long axis that is along the direction of C-C′ with a length L_{long}, and a short axis that is perpendicular to C-C′ with a length Lₛₕₒᵣₜ. When L_{long}/Lₛₕₒᵣₜ is one, the oval becomes a circle. It is preferred that L_{long}/Lₛₕₒᵣₜ is in a range between about 1 and about 3. It is also preferred that the tilt angle α is between about 20 and 70 degrees, although the tilt angle can be 0 to 20 degrees or 70 to 90 degrees. The slant contact has a preferred area of smaller than about 0.03 μm².

Although the previous embodiments illustrate the slant contact having length along x direction, the concept of the slant contact applies equally to the y direction. It is also appreciated that the slant contact can be used in any integrated circuit design and is not limited to SRAM cells only.

With the use of slant contacts, layout area can be used more efficiently. Also, the cross talk between contacts can be reduced. It is known that the cross talk between two conductors increases when the distance between the two conductors decreases. Cross talk is also related to the angle between the currents of the contacts, and is the highest when the currents are parallel and lowest when the currents are vertical to each other. By increasing the distance between contacts and increasing the tilt angle α (by using slant contacts), the cross talk can be significantly reduced. For example, if two contacts have a tilt angle α of about 15 to about 30 degrees, and assuming their distance is increased by 50% by slanting at least one of the contacts, the cross talk will be reduced to between about 5 percent to about 15 percent of the cross talk of two parallel contacts.

In addition to the slant contacts, techniques such as butted local interconnections, compound interconnections, and slim spacers can also be integrated into the IC design. The combination of these techniques further compacts SRAM cells. These techniques can be applied to the same device or different devices on the same chip. The preferred embodiments of the present invention use a six-transistor SRAM cell as an example to illustrate how the present invention fits into the IC design.

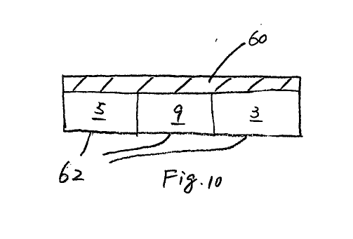

Cross-sectional views of several variations of the preferred embodiments are shown in FIGS. 8 through 10 wherein like reference numbers are used to designate like elements in FIG. 1 and FIG. 3. As discussed in previous paragraphs, the contacts 24 and 26 are preferably slant contacts. The size of the contacts 24 and 26 can be further reduced by using butted local interconnections, sometimes referred to as butted contacts. FIG. 8 illustrates a cross-sectional view of the contact 24 along line A-A′ as shown in FIG. 3. Region 56 is a shallow-trench-isolation (STI) region. A buried oxide 41 is formed on a substrate 40. The contact 24 is formed as a butted local interconnection and connects two features, the gate 6 of the transistor 18 and the drain 4 of the pull up transistor 12. It preferably touches the STI region 56, which includes at least a portion having a MESA structure. The contact 24 is preferably formed of tungsten, aluminum, copper, or other known alternatives. As known in the art, the butted local interconnection 24 can be formed by covering an undesired area with a photo resist (not shown), depositing a metal, removing the photo resist, and thus leaving the butted local interconnection 24. Preferably, the butted local interconnection 24 has a thickness H of about 500 Å to about 5000 Å, and more preferably about 2000 Å to about 4000 Å. The preferred width is about 0.05 μm to about 0.1 μm. To make the SRAM design compact, the length L is preferably between about 0.1 m and about 0.4 μm, more preferably between about 0.1 μm and about 0.2 μm. The distance between butted local interconnections is preferably less than about 0.14 μm, so that the layout area saved by using butted local interconnections is more significant.

FIG. 9 illustrates another embodiment of the butted local interconnection wherein the thickness H is less than the height of the gate 6.

By using the preferred embodiment of the present invention, the length L of the contact 24 is much smaller then the length of a conventional contact. In the conventional design, the minimum length is the length of two contacts plus the distance between the two contacts. In the preferred embodiment, only one contact is formed so that the length is reduced. The resistance of the contact is also decreased since the butted local interconnection 24 is formed of bulk material.

To further reduce the size of the SRAM cell, slim spacers 48 are formed, as illustrated in FIGS. 8 and 9. Since the contact 24 covers at least part of the spacer 48, reducing the width Ws of the spacer 48 causes the reduction of the length L of the contact 24. The slim spacers 48 preferably have a well-known oxide-nitride-oxide (ONO) structure, wherein the oxide layers are preferably formed of tetraethyl orthosilicate (TEOS) oxide formed by low-pressure chemical vapor deposition (LPCVD). The nitride layer is preferably formed by a LPCVD process to a thickness of greater than about 400 Å, and then reduced by a conventional nitride wet or dry etch. Preferably, in below-65 nm technology, the slim spacers 48 have a width Ws of less than about 350 Å. Other known methods can also be used to form the slim spacers 48.

Referring to FIG. 1, the source 2 of the pass gate transistor 10 is preferably connected to the drain 4 of the pull up transistor 12 and the drain 8 of the pull down transistor 14 by a compound interconnection. In a preferred embodiment, the compound interconnection is formed of a doped semiconductor covered with a silicide. Referring to FIG. 3, the compound interconnection is in a combined region of regions 3, 9 and 5. Region 3 is an extension of the n+ type region 2 of the transistor 10. Region 9 is an extension of the n+ type region 8 of the transistor 14. Region 5 is an extension of the p+ type region 4 of the transistor 12. In order to reduce production cost, the compound interconnection, which includes regions 3, 9 and 5, is preferably formed at the same time the respective active regions 2, 8 and/or 4 are formed.

FIG. 10 illustrates a cross-sectional view of the doped semiconductor 62, which is in a combined region of regions 3, 9 and 5, along line B-B′ in FIG. 3. The doped semiconductor 62 includes a p+ region 5 and n+ regions 3 and 9. A silicide 60 is formed on the doped semiconductor 62. The silicide 60 preferably comprises nickel, cobalt, platinum, or other known metals. The silicide 60 is combined with the doped semiconductor 62 to reduce the resistance of the interconnection and possible p-n junction effects between the p+ and n+ regions. Preferably, the silicide 60 has a thickness of about 15 nm to about 25 nm. The doped semiconductor 62 preferably has an impurity concentration of greater than about 1E14 cm⁻². The compound interconnection replaces the contacts and metals lines needed otherwise, thus saving layout area.

The small feature size of the preferred embodiment of the present invention demands finer resolution. To meet the demanding requirement of the preferred embodiment, it is preferred that the optical setting of the lithography tool has a numerical aperture of greater than about 0.7. Both dry and immersion lithography technologies can be used. Also, phase shift masks can be used to take advantage of interference to improve resolution and depth of focus in optical lithography.

The preferred embodiments of the present invention have several advantageous features. By combining various design techniques discussed in previous paragraphs, the preferred embodiments of the present invention significantly reduce the layout area of the integrated circuit. For example, a 6T SRAM cell designed using the preferred embodiments of the present invention occupies an area of about 0.5 μm² to about 0.15 μm² in 45 nm technology. The slant contact design makes layout more flexible and more compact. Cross talk between the contacts is reduced. These techniques can be combined in the same region of the integrated circuit or used in separate regions.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device comprising:
a first feature substantially aligned to a first direction;
a second feature substantially aligned to a second direction wherein the second direction is parallel or orthogonal to the first direction; and
a slant contact electrically connecting the first feature and the second feature.

2. The semiconductor device of claim 1 wherein the slant contact has a tilt angle of between about 20 degrees and about 70 degrees.

3. The semiconductor device of claim 1 wherein the slant contact comprises a metal selected from the group consisting essentially of aluminum, copper and combinations thereof.

4. The semiconductor device of claim 1 wherein the slant contact is formed of a material comprising tungsten.

5. The semiconductor device of claim 1 further comprising a butted local interconnection connecting a third feature and a fourth feature.

6. The semiconductor device of claim 5 wherein the butted local interconnection physically touches a shallow trench isolation region.

7. The semiconductor device of claim 6 wherein at least a portion of the shallow trench isolation region has a MESA structure.

8. The semiconductor device of claim 5 wherein the butted local interconnection connects a gate and an active region, and wherein the gate comprises:
a gate dielectric formed of an oxide-based material having a dielectric constant (K) value of greater than about 5;
a gate electrode on the gate dielectric; and
a spacer on a sidewall of the gate electrode.

9. The semiconductor device of claim 8 wherein the spacer has a width of less than about 350 Å.

10. The semiconductor device of claim 8 wherein the gate electrode belongs to a first transistor and the active region belongs to a second transistor.

11. The semiconductor device of claim 5 further comprising a second butted local interconnection in contact with a gate of a third transistor and a source/drain region of a fourth transistor wherein the first and the second butted local interconnections have a distance of less than about 0.14 μm.

12. The semiconductor device of claim 1 wherein the slant contact has a long axis and a short axis and wherein the ratio of the long axis to the short axis is between about 1 and about 3.

13. The semiconductor device of claim 1 further comprising:
a first, second, and third transistor in a third region;
wherein the source of the first transistor is connected the drain of the second transistor and the drain of the third transistor by a compound interconnection comprising a doped semiconductor and a silicide on the doped semiconductor;
wherein the doped semiconductor has a p+ region and an n+ region connected in series and physically contacts each other; and
wherein the drain of the second transistor is connected to the gate of the third transistor through a butted local interconnection.

14. A semiconductor device comprising:
a first, second, and third transistor;
wherein the source of the first transistor is connected the drain of the second transistor and the drain of the third transistor by a compound interconnection comprising a doped semiconductor and a silicide on the doped semiconductor;
wherein the doped semiconductor has a p+ region and an n+ region connected in series and physically contacting each other; and
wherein the drain of the second transistor is connected to the gate of the third transistor through a butted local interconnection.

15. The semiconductor device of claim 14 wherein the butted local interconnection comprises a metal selected from the group consisting essentially of aluminum, copper, and combinations thereof.

16. The semiconductor device of claim 14 wherein the butted local interconnection comprises tungsten.

17. The semiconductor device of claim 14 wherein the butted local interconnection is a slant contact, and wherein the slant contact physically touches a shallow trench isolation region.

18. The semiconductor device of claim 17 wherein at least a portion of the shallow trench isolation region has a MESA structure.

19. The semiconductor device of claim 14 wherein the third transistor comprises a gate comprising:
a gate dielectric formed of an oxide-based material having a K value of greater than about 5;
a gate electrode on the gate dielectric; and a spacer on a sidewall of the gate electrode.

20. The semiconductor device of claim 19 wherein the spacer of the third transistor has a width of less than about 350 Å.

21. The semiconductor device of claim 14 wherein the silicide is a metal silicide comprising a metal selected from the group consisting essentially of nickel, platinum, and combinations thereof.

22. The semiconductor device of claim 14 wherein the silicide comprises cobalt.

23. A method of forming an SRAM cell, the method comprising:
providing a chip;
providing a first feature substantially aligned to a first direction on the chip;
providing a second feature substantially aligned to a second direction on the chip wherein the second direction is parallel or orthogonal to the first direction; and
providing a mask comprising a first portion and a second portion to form a slant contact in a first region of the chip, wherein the second portion is connected to the first portion and shifted a distance less than a whole dimension of the slant contact along the direction shifted.

24. The method of claim 23 further comprising:
providing a second region on the chip;
forming a first and second transistor; and
forming a butted local interconnection connecting a gate of the first transistor and an active region of the second transistor.

25. The method of claim 24 wherein forming the first transistor comprises forming a slim spacer having a width of less than about 350 Å, and wherein the butted local interconnection covers at least a portion of the slim spacer.

26. The method of claim 23 further comprising:
simultaneously forming a first extension of a drain of the first transistor when the source of the first transistor is formed;
simultaneously forming a second extension of a drain of a third transistor when the drain of the third transistor is formed;
simultaneously forming a third extension of a source of a fourth transistor when the source of the fourth transistor is formed;
wherein the first, second and third extensions are serially connected; and
forming a silicide on the first, second and third extensions.
